(19) United States
(12) Patent Application Publication
(10) Pub. No.: US 2014/0269073 A1
(43) Pub. Date: Sep. 18, 2014

(54) SEMICONDUCTOR MEMORY DEVICE

(71) Applicant: Kabushiki Kaisha Toshiba, Minato-ku (JP)

(72) Inventor: Kiyotaro ITAGAKI, Kanagawa-ken (JP)

(73) Assignee: Kabushiki Kaisha Toshiba, Minato-ku (JP)

(21) Appl. No.: 14/021,243

(22) Filed: Sep. 9, 2013

(30) Foreign Application Priority Data
Mar. 14, 2013 (JP) 2013-051591

(51) Int. Cl. G11C 16/26; G11C 16/32

(52) U.S. Cl. CPC G11C 16/26; G11C 16/32
USPC 365/185.11

(57) ABSTRACT

An aspect of the present embodiment, there is provided a semiconductor memory device including memory cell arrays, each of the memory cell arrays including memory cells, including a clock generator configured to generate clock, an input-output circuit configured to input and output data, buses, a portion of each of the buses crossing the memory cell arrays, switches, each of the switches being placed in the bus, control circuit configured to control the switches to generate a path which transfers clock and data without overlapping with an activated memory cell as viewed from above.

### CROSS REFERENCE TO RELATED APPLICATION

This application is based upon and claims the benefit of priority from prior Japanese Patent Application No. 2013-051591, filed on Mar. 14, 2013, the entire contents of which are incorporated herein by reference.

### FIELD

Exemplary embodiments described herein generally relate to a semiconductor memory device.

### BACKGROUND

A NAND-type flash memory in which memory cells are three-dimensionally arranged is well known.

### BRIEF DESCRIPTION OF THE DRAWINGS

FIG. 1 is a block diagram showing a semiconductor memory device according to a first embodiment;

FIG. 2 is a block diagram showing a memory cell array according to the first embodiment;

FIG. 3 is a circuit diagram showing the memory cell array according to the first embodiment;

FIG. 4 is a block diagram showing the semiconductor memory device according to the first embodiment;

FIG. 5 is a diagram showing action of a signal transfer unit according to the first embodiment;

FIG. 6 is a block diagram showing the semiconductor memory device according to the first embodiment;

FIG. 7 is a block diagram showing the semiconductor memory device according to the first embodiment;

FIG. 8 is a block diagram showing the semiconductor memory device according to the first embodiment;

FIG. 9 is a block diagram showing the semiconductor memory device according to the first embodiment;

FIG. 10 is a block diagram showing a semiconductor memory device according to a second embodiment;

FIG. 11 is a diagram showing action of a signal transfer unit according to the second embodiment;

FIG. 12 is a block diagram showing the semiconductor memory device according to the second embodiment;

FIG. 13 is a block diagram showing a semiconductor memory device according to a modification of the first and second embodiments;

FIG. 14 is a cross-sectional view showing a semiconductor memory device according to a modification of the first and second embodiments;

FIG. 15 is a circuit diagram showing a memory cell array according to a modification of the first and second embodiments.

### DETAILED DESCRIPTION

An aspect of one embodiment, there is provided a semiconductor memory device including memory cell arrays, each of the memory cell arrays including memory cells, including a clock generator configured to generate clock, an input-output circuit configured to input and output data, buses, a portion of each of the buses crossing the memory cell arrays, switches, each of the switches being placed in the bus, control circuit configured to control the switches to generate a path which transfers clock and data without overlapping with an activated memory cell as viewed from above.

Embodiments will be described below in detail with reference to the attached drawings mentioned above.

Throughout the attached drawings, similar or same reference numerals show similar, equivalent or same components, and the description is not repeated.

### 1. First Embodiment

A semiconductor memory device according to a first embodiment is described below.

A NAND-type flash memory of a three-dimensionally stacked type, in which memory cells are stacked above an upper portion of a semiconductor substrate, is explained, for example.

1.1 Constitution of Semiconductor Memory Device

First, a constitution of the semiconductor memory device according to the embodiment is explained.

1.1.1 Whole Constitution of Semiconductor Memory Device

FIG. 1 is a block diagram showing the semiconductor memory device according to the first embodiment. As shown in FIG. 1, a NAND-type flash memory 1 includes a plurality of planes 10, an input-output circuit 20, a clock generator 30, a signal transfer unit 40 and a control circuit 50. In addition, three planes 10-0, 10-1, 10-2 are shown as the planes 10, for example.

Each of planes 10 includes a memory cell array 11, a sense amplifier 12 and a row decoder 13. In explanation described below, when the blocks are distinguished between the planes 10-0˜10-2, the same suffix is provided on the reference code. The memory cell array 11 includes a plurality of memory cells to retain data in nonvolatile. The sense amplifier 12 senses and amplifies data read from the memory cell array 11 to temporarily retain the data. The sense amplifier 12 temporarily retain the data written into the memory cell array 11 to write data to the memory cells on a basis of the data. The row decoder 13 selects a row direction of the memory cell array 11.

The input-output circuit 20 conducts data transfer to a controller or host equipment outside the NAND-type flash memory 1. The input-output circuit 20 includes a FIFO (First-In First-Out) memory 21 and a data driver 22. The FIFO memory 21 is received clock CLK and data DOUT from the signal transfer unit 40. The FIFO memory 21 synchronizes clock CLK with output data DOUT to serially output the data to an outer portion. The data driver 22 is received data DIN from an outer portion.

The clock generator 30 generates clock CLK.

The signal transfer unit 40 includes buses transmitting signals and a plurality of switches. The signal transfer unit 40 transfers clock CLK generated by the clock generator 30 to the sense amplifier 12 and the FIFO memory 21 by using the buses and the switches. The signal transfer unit 40 transfers data DOUT read out from each of sense amplifiers 12-0˜12-2 to the FIFO memory 21 and transfers data DIN from the data driver 22 to each of the sense amplifiers 12-0˜12-2. The signal transfer unit 40 is described later in detail.

1.1.2 Memory Cell Array

Next, the memory cell array 11 is described in detail using FIG. 2. FIG. 2 is a block diagram showing a memory cell array.

As shown in FIG. 2, the memory cell array 11 includes a plurality of blocks BLK (BLK0, BLK1, BLK2 . . . BLKN, for example), each of the blocks assembling nonvolatile memory cells. The data in the same block BLK is collectively erased. Each of the blocks BLK includes a plurality of memory groups GP (GP0, GP1, GP2 . . . GPM, for example) assembling NAND strings 14 in which the memory cells are serially connected. A numbers of the blocks in the memory cell array 11 and the memory groups in the block can be arbitrarily determined.

A constitution of each of the blocks BLK is explained in detail using FIG. 3. FIG. 3 is a circuit diagram showing the memory cell array according to the first embodiment. Other block BLK includes the same constitution as the circuit diagram described in FIG. 3.

As shown in FIG. 3, the block BLK0 includes the plurality of memory groups GP, and each of the memory groups GP includes the plurality of the NAND strings 14, for example, L numbers of NAND strings 14.

Each of the NAND strings 14 includes eight memory cell transistors MT (MT0˜MT7), for example, select transistors ST1, ST2 and a back gate transistor BT. Each of the memory cell transistors MT includes a stacked gate having a control gate and a charge accumulation layer to retain data in nonvolatile. A number of memory cell transistors MT is not restricted to eight. The number can be set to sixteen, thirty-two, sixty-four, one hundred and twenty-eight or the like. The back gate transistor BT also includes a stacked gate having a control gate and a charge accumulation layer as the same as the memory cell transistor MT. On the other hand, the back gate transistor BT can not retain data, and merely function as a current pass when data is written and erased. Each of the memory cell transistor MT and the back gate transistor BT is arranged between the select transistors ST1, ST2 so that the current pass is serially connected in between. The back gate transistor BT is arranged between the memory cell transistors MT3, MT4. The current pass of the memory cell transistor MT7 at one terminal of the serial connection connects to one terminal of the current pass of the select transistor ST1, and the current pass of the memory cell transistor MT0 at the other terminal of the serial connection connects to one terminal of the current pass of the select transistor ST2.

A gate of each select transistor ST1 of the memory groups GP0˜GP(M−1) commonly connects to each of select gate lines SGS0˜SGS(M−1) and a gate of each select transistor ST2 commonly connects to each of select gate lines SGS0˜SGS(M−1). On the other hand, each control gate of the memory cell transistors MT0˜MT7 in the same block BLK0 commonly connects to each of word lines WL0˜WL7. A control gate of the back gate transistor BT connects to the back gate line BG. Each control gate in the blocks BLK0˜BLK(N−1) commonly connects to each of the back gate lines BG0˜BG(N−1).

Namely, the word lines WL0˜WL7 and the back gate line BG are commonly connected between the plurality of memory groups GP in the same block BLK0. On the other hand, each of the select gate lines SGD, SGS is independent every memory groups GP even in the same block BLK0.

The other terminal of the current pass of the select transistor ST1 of the NAND string 14 in the same column of the NAND strings 14 arranged as a matrix in the memory cell array 11 is commonly connected to one of the bit lines BL. Namely, the bit line BL commonly connects the NAND string 14 between the blocks BLK. The other terminal of the current pass of the select transistor ST connects to one of the source lines SL. The source line SL commonly connects the NAND strings 14 between the memory groups GP, for example.

As described above, data of the memory cell transistors MT in the same block BLK are collectively erased. On the other hand, reading or writing on data is collectively performed on the memory cell transistors MT which are commonly connected to one of the word lines WL in one of the block BLK in one of the memory group GP. This unit is called a page.

In the constitution of the memory cell array 11 described above, the memory cell transistors MT, the select transistors ST1, ST2 and the back gate transistor BT are three-dimensionally stacked above the semiconductor substrate.

A portion of periphery circuits, for example, the sense amplifier 12 is provided above the semiconductor substrate, and the memory cell array 11 is provided above the periphery circuits, as one example.

1.1.3 Sense Amplifier

Next, a constitution of the sense amplifier 12 is explained using FIG. 4. FIG. 4 is a block diagram showing the NAND-type flash memory 1, especially, the sense amplifier 12 and the signal transfer unit 40.

As shown in FIG. 4, the sense amplifier 12 includes latch circuits LAT (LAT0˜LAT2) for cashing action. Each of the latch circuit LAT receives the clock CLK to act and output the clock CLK. Further, the latch circuit LAT receives data DIN and outputs the data DOUT. Data DIN is provided from the data driver 22 which is written in the memory cell array 11 and data DOUT is read out from the memory cell array 11.

The sense amplifier 12 includes other latch circuit (not shown) and a bit line control unit. The latch circuit receives data DIN from the latch circuit LAT when data is written in the memory cell array 11, and sends data DOUT to the latch circuit LAT when data is read out in the memory cell array 11. The bit line control unit applies voltage to the bit line on a basis of data DIN in the latch circuit when data is written in the memory cell array 11, and stores data read out as data DOUT in the latch circuit when data is read out.

As described above, the latch circuit LAT acts for cashing action. Accordingly, the plane 10-0 can be accessed to the latch circuit LAT0 in a case that the latch circuit LAT0 is empty, during data is written in the memory cell array 11, for example. Furthermore, data DIN can be stored in the latch and data DOUT is read out from the circuits LAT1, LAT2 during data is written in the plane 10-0, for example.

1.1.4 Signal Transfer Unit 40

Next, the signal transfer unit 40 is explained in detail using FIG. 4, successively.

As shown in FIG. 4, the signal transfer unit 40 includes a data bus BD, a clock input bus BCI and a clock output bus BCO, and a plurality of switches provided in the buses, and switches SW0-SW5, SW10-SW12, SW20, SW21, SW30-SW35, SW40-SW42 and SW50.

The buses BD, BCI, BCO are provided as a ring shape as shown in FIG. 4. A portion of the ring shape crosses the plane 11-0˜11-2 (memory cell array 11-0˜11-2) and the residual portion is arranged not to overlap with the plane 11-0˜11-2. The bus BD transfers data DOUT outputted from the latch circuit LAT to the FIFO memory 21. The bus BCI transfers clock CLK generated in the clock generator 30 to the latch circuit LAT. The bus BCO transfers clock CLK outputted form the latch circuit LAT to the FIFO memory 21.

The bus BD includes buses BD0-BD4. The bus BD0 is connected to the latch circuit LAT0 via the switches SW30, SW40, connected to the bus BD1 via the switches SW30, SW31, and connected to the bus BD4 via switch SW51. A portion of the bus BD0 is positioned an area below the memory cell array 11-0 and is connected to the switch SW30, and the residual portion of the bus BD0 is positioned not to overlap with all of the memory cell arrays 11-0˜11-2 to be connected to the switch SW51.

The bus BD1 is connected to latch circuit LAT0 via the switches SW31, SW40, connected to the latch circuit LAT1 via the switches SW32, SW41 and connected to the bus BD2 via the switches SW32, SW33. The bus BD1 is positioned an area below the memory cell array 11-1.

The bus BD2 is connected to the latch circuit LAT1 via the switches SW33, SW41, connected to the latch circuit LAT2 via the switches SW34, SW42 and connected to the bus BD3 via the switches SW34, SW35. The bus BD2 is positioned an area below the memory cell array 11-2.

The bus BD3 is connected to the latch circuit LAT2 via the switch SW35, SW42, connected to the bus BD4 via the switch SW5. The bus BD3 is positioned not to overlap with the memory cell arrays 11-0˜11-2.

The bus BD4 also is positioned not to overlap with the memory cell arrays 11-0˜11-2 and is connected to a data input terminal DAT of the FIFO memory 21.

Next, the buses BCI, BCO are explained below. Each of the buses BCI, BCO includes buses BCI0˜BCI4 and buses BCO0˜BCO4. The bus BCI0 and the bus BCO0 are connected to the latch circuit LAT0 via the switch SW0 and the switch SW10, connected to the bus BCI1 and the bus BCI1 via the switch SW0 and the switch SW1, and connected to the bus BCI4 and the bus BCO4 via the switch SW21, respectively. One portion of each of the bus BCI0 and the bus BCO0 is positioned an area below the memory cell array 11-0 to be connected to the switch SW0 and the residual portion of each of the bus BCI0 and the bus BCO0 is positioned not to overlap with all of the memory cell array 11-0˜11-2 to be connected to the switch SW21.

The bus BCI1 and the bus BCI1 are connected to the latch circuit LAT0 via the switch SW1 and the switch SW10, connected to the latch circuit LAT1 via the switch SW2 and the switch SW1, and connected to the bus BCI2 and the bus BCO2 via the switch SW2 and the switch SW3, respectively. The bus BCI1 and the bus BCO1 are positioned an area below the memory cell array 11-1.

The bus BCI2 and the bus BCO2 are connected to the latch circuit LAT1 via the switch SW3 and the switch SW11, connected to the latch circuit LAT2 via the switch SW4 and the switch SW12, and connected to the bus BCI3 and the bus BCO3 via the switch SW4 and the switch SW5, respectively. The bus BCI2 and the bus BCO2 are positioned an area below the memory cell array 11-2.

The bus BCI3 and the bus BCO3 are connected to the latch circuit LAT2 via the switch SW5 and the switch SW12, and connected to the bus BCI4 and the bus BCO4 via the switch SW20, respectively. The bus BCI3 and the bus BCO3 are positioned not to overlap with the memory cell arrays 11-0˜11-2.

The bus BCI4 and the bus BCO4 are also positioned not to overlap with the memory cell arrays 11-0˜11-2, and is connected to a clock output terminal of the clock generator 30 and a clock input terminal CLKIN of the FIFO memory 21.

The switches SW10˜SW12, SW40˜SW42 are explained as a portion of the signal transfer unit 40 below. However, the switches SW10˜SW12, SW40˜SW42 may be a portion of the sense amplifier 12.

1.2 Data Output Action

Next, data output action of each of the planes 10 is explained below especially in focusing on action of the signal transfer unit 40.

FIG. 5 is a diagram showing action state of the signal transfer unit 40 as an example when data is read from the latch circuit LAT0 of the plane 10-0. In FIG. 5, “0” means that a first voltage is applied to a gate of the switch and “1” means that a second voltage is applied to the gate of the switch, where the first voltage is lower than the second voltage. As shown in FIG. 5, control of the switches is dependent on a case that any of memory cell arrays 11 is activated, namely data is accessed or not, when data is read from the latch circuit LAT0. The control is performed by the control circuit 50, for example. The control circuit 50 controls to form a transfer path of data and clock without using the buses below activated memory cell array. Explanation is specifically conducted below. On the other hand, the transfer path of data and clock is not restricted when all of the memory cell arrays 11 are not activated.

A case of reading data from the latch circuit LAT0 when the memory cell array 11-0 is activated using FIGS. 5, 6. FIG. 6 is a block diagram easily showing the signal transfer path as shown in FIG. 4. The buses indicated with broken lines mean not to act as the signal path and the block indicated with diagonal lines is an object to be accessed.

As shown in FIG. 5, the control circuit 50 set the switches SW0, SW30, SW21, SW51 to be off. In such a manner, buses BCI0, BCO0, BD0 are electrically separated from the sense amplifier 12-0, the clock generator 30 and the FIFO memory 21 as shown in FIG. 6. The control circuit 50 sets the switches SW11, SW41, SW12, SW42 to be off, as the latch circuits LAT1, LAT2 are not included in the objects to be accessed. The other switches are set to be on.

As a result described above, a clock transfer path from the clock generator 30 to the latch circuit LAT0 provided with the buses BCI1-BCI4 via the switches SW10, SW1˜SW5, SW20. A clock transfer path from the latch circuit LAT0 to the FIFO memory 21 is provide with the buses BCO1˜BCO4 via the switches SW10, SW1˜SW5, SW20. Further, a data transfer path from the latch circuit LAT0 to the FIFO memory 21 is provided with the bus BD1˜BD4 via the switches SW40, SW31˜35, SW50.

A case of reading data from the latch circuit LAT0 when the memory cell array 11-1 is activated using FIGS. 5, 7. As shown in FIG. 5, the control circuit 50 set the switches SW0, SW30, SW10, SW40, SW51 to be on and the other switched to be off. In such a manner, buses BCI1-BCI3, BCO1-BCO3, BD1˜BD3 are electrically separated from the sense amplifier 12-0, the clock generator 30 and the FIFO memory 21 as shown in FIG. 7.

As a result described above, the clock transfer path from the clock generator 30 to the latch circuit LAT0 provided with the buses BCI1˜BCI4 via the switches SW10, SW0, SW21. The clock transfer path from the latch circuit LAT0 to the FIFO memory 21 is provided with the buses BCO0, BCI4 via the switches SW10, SW0, SW21. Further, the data transfer path from the latch circuit LAT0 to the FIFO memory 21 is provided with the bus BD0, BD4 via the switches SW40, SW30, SW51.

A case of reading data from the latch circuit LAT0 when the memory cell array 11-2 is activated using FIGS. 5, 8. Such a case is the same as the case where the memory cell array 11-1 is activated described above as shown in FIG. 7.

The signal transfer path is provided without using the buses below the activated memory cell array as the same as the above case, when accessing to the latch circuits LAT1, LAT2. In a case of accessing to the latch circuit LAT1, the buses BCI0·BCI1, BCO0˜BCO1, BD0˜BD1 are not used but the buses BCI2˜BCI4, BCO2˜BCO4, BD2˜BD4 are used when the memory cell array 11-0 or the memory cell array 11-1 is activated. On the other hand, in a case of accessing to the latch circuit LAT1, the buses BCI2, BCO2, BD2 are not reversely used but the buses BCI0˜BCI1, BCI4, BCO0˜BCO1, BCO4, BD0˜BD1, BD4 are used when the memory cell array 11-2 is activated.

1.3 Effects of the Embodiment

The constitution of the embodiment can make a chip area of a NAND-type flash memory shrink. The effects are described below.

In a NAND-type flash memory including a plurality of planes, signal paths acting as transferring both clocks to each of the planes and data from each of the planes are necessary. In a case where the signal paths are simply arranged, a layout drawn in FIG. 9 is considered, for example. FIG. 9 is a block diagram showing a NAND-type flash memory according to a comparative case of the first embodiment. However, in a wiring layout in FIG. 9, extra space is necessary every planes to increase the chip size.

On the other hand, a wiring layout has loop shapes as shown in FIG. 4 and a portion of each of the loop shapes is overlapped with the planes 10 to cross the planes 10 according to the first embodiment. The wiring having the lop shape is connected to the sense amplifier 12 of the plane 10 at a portion to be overlapped. Therefore, a wiring area can be decreased as compared to that of the layout of FIG. 9 as shown in FIG. 4. At least a wiring area between adjacent planes 10 is not necessary in FIG. 9, for example. Accordingly, the chip area of the NAND-type flash memory 1 can be shrunk.

Furthermore, the constitution of the NAND-type flash memory 1 according to the first embodiment can improve reliability of memory action. As described in the comparative case, any of the memory cell arrays is activated to consider affecting degradation of signal propagation in a case that a signal wiring on clock or data is overlapped with the planes 10.

Higher program voltage is applied to a select word line when data is written in the memory cell, for example. Higher erase voltage is applied to a bit line and a source line when data is erased in the memory cell, for example. Switching action of an “H” level and an “L” level is repeatedly conducted using the high voltages in the activated memory cell array. In a signal wiring near a region where such the larger voltage variation is generated, a wave form transmitted via the signal wiring may be deformed or be delayed, or the information may be destroyed by influence of capacitance coupling or the like.

On the other hand, the constitution of the first embodiment includes the loop-shaped signal wirings transferring clock CLK and data DOUT and the switches to be configured to separate the plurality of the regions. Further, in a case that any of memory cell arrays 11 activated, the wirings below the activated memory cell array 11 is not used but the other wirings are used to connect between the planes 10 and the both clock generator 30 and the FIFO memory 21. Consequently, the signal can be transmitted without influence from the activated memory cell arrays. Therefore, NAND-type flash memory 1 can obtain higher reliability of memory action.

### 2. Second Embodiment

A semiconductor memory device according to a second embodiment is explained. The first embodiment focuses on the case where data DOUT is outputted from the sense amplifier 10. On the other hand, the second embodiment focuses on the case where data DIN is inputted into the sense amplifier 10. Different points from the firs embodiment are only described below.

2.1 Signal Transfer Unit 40

A signal transfer unit 40 according to the second embodiment is described using FIG. 10 below. FIG. 10 is a block diagram showing a NAND-type flash memory 1, especially, a sense amplifier 12 and the signal transfer unit 40 in detail.

As shown in FIG. 10, the signal transfer unit 40 includes a data bus BD and a clock input bus BCI, and a plurality of switches provided in the buses, switches SW0-SW5, SW10-SW12, SW20, SW21.

The buses BD, BCI are described as a ring shape in layout as the same as the first embodiment. The bus BD transfers data DIN written from data driver 22a to the latch circuit LAT. The bus BCI transfers clock CLK generated in the clock generator 30 to the latch circuit LAT. The bus BD includes buses BD0˜BD4 and the bus BCI includes buses BCI0˜BCI4 as the same as the first embodiment.

The buses BD0, BCI0 are connected to the latch circuit LAT0 via the switches SW0, SW10, connected to the buses BD1 and BCI1 via the switches SW0, SW1, and connected to the bus BD4, BCI4 via switches SW21. A portion of each of the buses BD0, BCI0 is positioned an area below the memory cell array 11-0 and is connected to the switch SW0, and the residual portion of each of the buses BD0, BCI0 is positioned not to overlap with all of the memory cell arrays 11-0˜11-2 to be connected to the switch SW21.

The buses BD1 BCI1 are connected to the latch circuit LAT0 via the switch SW1, SW10, connected to the latch circuit LAT1 via the switches SW2, SW11 and connected to the buses BD2, BCI2 via the switches SW2, SW3, respectively. The buses BD1, BCI1 are positioned an area below the memory cell array 11-1.

The buses BD2, BCI2 are connected to the latch circuit LAT1 via the switch SW3, SW11, connected to the latch circuit LAT2 via the switch SW4, SW12 and connected to the buses BD3, BCI3 via the switch SW4, SW5. The buses BD2, BCI3 are positioned an area below the memory cell array 11-2.

The buses BD3, BCI3 are connected to the latch circuit LAT2 via the switch SW5, SW12, connected to the bus BD4 and BCI4 via the switch SW20. The buses BD3, BCI3 are positioned not to overlap with the memory cell arrays 11-0˜11-2.

The buses BD4, BCI4 are also positioned not to overlap with the memory cell arrays 11-0˜11-2 and is connected to a data input terminal DAT of the data driver 22 and a clock output terminal of the clock generator 30.

2.2 Data Output Action

Next, data input action to each of the planes 10 is explained below, especially in focusing on action of the signal transfer unit 40.

FIG. 11 is a diagram showing action state of the signal transfer unit 40 as an example when data is read from the latch circuit LAT0 of the plane 10-0. In FIG. 11, “0” means that the switch is set to be off and “1” means that the switch is set to be on, as the same as FIG. 5. The control circuit 50 controls to form a transfer path of data and clock without using the buses below activated memory cell array as the same as the first embodiment. Explanation is specifically conducted below.

A case of outputting data into the latch circuit LAT0 when the memory cell array 11-0 is activated using FIGS. 11, 12.

As shown in FIG. 11, the control circuit 50 set the switches SW0, SW21 to be off. In such a manner, buses BD0, BCO0, are electrically separated from the sense amplifier 12-0, the clock generator 30 and the data driver 22 as shown in FIG. 12. The control circuit 50 sets the switches SW11, SW12 to be off, as the latch circuits LAT1, LAT2 are not included in the objects to be accessed. The other switches are set to be on.

As a result described above, a transfer path from the clock generator 30 to the latch circuit LAT0 provided with the buses BCI1˜BCI4 via the switches SW10, SW1˜SW5, SW20.

A transfer path of data DIN from the latch circuit LAT0 to the data driver 22 is provide with the buses BD1˜BD4 via the switches SW10, SW1˜SW5, SW20.

In a case where the memory cell arrays 11-1, 11-2 are activated, the results are the same as shown in FIG. 11. The signal transfer path is provided without using the buses below the activated memory cell array when transferring data DIN to the latch circuits LAT1, LAT2 (not shown). In a case of inputting data DIN to the latch circuit LAT1, the buses BCI0˜BCI1, BD0˜BD1 are not used but the buses BCI2˜BCI4, BD2˜BD4 are used when the memory cell array 11-0 or the memory cell array 11-1 is activated. On the other hand, in a case of accessing to the latch circuit LAT1, the buses BCI2, BD2 are not reversely used but the buses BCI0˜BCI1, BCI4, BD0˜BD1, BD4 are used when the memory cell array 11-2 is activated.

2.3 Effects of the Second Embodiment

The constitution of the second embodiment can obtain the same effects as the first embodiment in a case where data DIN is written in the sense amplifier.

### 3. Modification

As described above, the semiconductor memory device according to the first and second embodiments includes a plurality of memory cell arrays 11 in FIG. 1, a clock generator 30 in FIG. 1, an input-output circuit 20 in FIG. 1, buses BD, BCI, BCO in FIG. 4, switches SW in FIG. 4, and a control circuit 50 in FIG. 1. Each of the memory cell arrays 11 in FIG. 1 includes a plurality of memory cells. The clock generator 30 in FIG. 1 generates clock. The input-output circuit 20 in FIG. 1 sends and receives data. The buses BD, BCI, BCO in FIG. 4 are positioned such that a portion of each of the buses BD, BCI, BCO crosses the memory cell arrays. The switches SW in FIG. 4 are arranged in the buses. The control circuit 50 controls the switches to generate a signal path in which clock and data are transferred using the buses without including a path which is overlapped with the activated memory cell arrays (FIG. 5-8). The constitution described above can shrink a chip area in the semiconductor memory device.

Furthermore, the constitution according to the embodiments can include features described below. The semiconductor memory device further includes a plurality of sense amplifiers. Each of the memory cell arrays includes first and second memory cell arrays 11-0, 11-2 in FIG. 4. The sense amplifiers include a first sense amplifier 12-0 corresponded to the first memory cell array 11-0 and a second sense amplifier 12-1 corresponded to the second memory cell array 11-1 as shown in FIG. 4. The buses includes first-third buses BCI0, BCO0, BD0/BCI1, BCO1, BD1/BCI3, BCO3, BD3 in FIG. 4. The switch includes first to eighth switch (SW10, SW40/SW0, SW30/SW1, SW31/SW11, SW41/SW2, SW32/SW3, SW33/SW20, SW50/SW21, SW51 in FIG. 4.

A portion of each of the first buses BCI0, BCO0, BD0 is overlapped with the first memory cell array 11-0 and the residual portion of each of the first buses BCI0, BCO0, BD0 is not overlapped with the memory cell array 11-0 as shown in FIG. 4. Each of the second buses BCI1, BCO1, BD1 is overlapped with the second memory cell array 11-1 as shown in FIG. 4. Each of the third buses BCI3, BCO3, BD3 is not overlapped any of the memory cell arrays as shown in FIG. 4. The first sense amplifier 12-0 is connected to the first buses BCI0, BCO0, BD0 via the first and second switches SW10, SW40/SW0, SW30, connected to the first and second buses BCI1, BCO1, BD1 via the third switches SW10, SW40/SW1, SW31. The second sense amplifier 12-1 is connected to the second buses BCI1, BCO1, BD1 via the fourth and fifth switches SW11, SW41/SW2, SW32, and connected to the third bus BCI3, BCO3, BD3 via the fourth and sixth switches SW11, SW41/SW3, SW33. The third buses BCI3, BCO3, BD3 are connected to the clock generator and the input-output circuit via the seventh switches SW20, SW50. The first buses BCI0, BCO0, BD0 are connected to the clock generator and the input-output circuit via eighth switch (SW21, SW51).

Action of the semiconductor memory device having the constitution described above can be controlled below. Namely, when the first sense amplifier 12-0 is accessed, the first voltage is applied to gates of the second, fourth, eighth switches SW0, SW30/SW11, SW41/SW21, SW51) and the second voltage is applied to gates of the first, third, fifth-seventh switches (SW10, SW40/SW1, SW31/SW2, SW32/SW3, SW33/SW20, SW50 as shown in FIG. 6 in a case that the first memory cell array is activated in FIG. 5-6. On the other hand, the first voltage is applied to the gates of the third-seventh switches SW1, SW31/SW11, SW41/SW2, SW32/SW3, SW33/SW20, SW50 and the second voltage is applied to gates of the first, second, eighth switches SW10, SW40/SW0, SW30/SW21, SW51 as shown in FIG. 7 in a case that the second memory cell array is activated as shown in FIGS. 5, 7.

Embodiments are not restricted to the above cases. Modifications are applicable. Each of the first and second embodiments can be independently performed or both the embodiments can be combined. The signal transfer unit 40 in detail is shown in FIG. 13, in a case of combination of the two embodiments. In such a case, the data bus BD can be used for transferring data from the sense amplifier 12 to the FIFO memory 21 and for transferring data from the data driver 22 to the sense amplifier 12. Further, the specified bus can be used in each case.

As described above, the memory cell array 11 and the sense amplifier 12 can be stacked above the semiconductor substrate and both of them can be overlapped in vertical direction of a surface of the semiconductor substrate. FIG. 14 shows the stacked structure of the memory cell array and the sense amplifier. FIG. 14 is a cross-sectional view simply showing the NAND-type flash memory 1, especially a portion only including the planes 11-0, 11-1.

As shown in FIG. 14, the sense amplifier 12 is provided on the semiconductor substrate 100. An insulator (not shown) is formed above the semiconductor substrate 100 to cover the sense amplifier 12, and the buses BD0, BD1 and the buses BCI, BCO (not shown) are formed in the insulator. Further, the memory cell arrays 11-0, 11-1 formed on the insulator and the bit line BL is connected to the sense amplifiers 12-0, 12-1 via contact plug CP0.

The memory cell array 11 and the sense amplifier 12 in the constitution can be overlapped to decrease a chip area of the NAND type flash memory 1.

The signal transfer unit 40 is not restricted to the constitutions as shown in FIGS. 4, 10, 13. A constitution including a path, which can avoid influence of the activated memory cell array 11, may be utilized. Accordingly, combination of the switches and the buses can be suitably selected and a layout of the bus is not necessary to have the loop shape.

The three-dimensionally stacked type of an NAND-type flash memory as the semiconductor memory device in the embodiment is explained. The three-dimensionally stacked type is not restricted to a prescribed structure, but may have a constitution with an equivalent circuit as shown FIG. 2. The transistors MT0˜MT7 can be stacked in a vertical direction of the semiconductor substrate. A serially connection of the transistors MT0˜MT7 can be arranged as a U-type above the semiconductor substrate. The embodiment is not restricted to the three-dimensionally stacked type, but can be applied to a conventional NAND-type flash memory arranged two-dimensionally in a surface of the semiconductor substrate.

The memory cell array as shown in FIG. 2 can be constituted as shown in FIG. 15. FIG. 15 is a circuit diagram showing the block BLK0 which can constitute other block BLK. As shown in FIG. 15, each of the memory groups GP includes dummy word lines WLDD, WLDS adjacent to the select gate lines SGD, SGS, respectively. The dummy word line WLDD adjacent to the word lines WL0˜WL3, the back gate line BG adjacent to the word line WL0, an even-ordered select gate lines SGD0, SGD2 and odd-ordered select gate lines SGS1, SGS3 are drawn to one end of the memory cell array 11. On the other hand, the dummy word lines WLDS adjacent to the word lines WL4˜WL7 and the word line WL7, even-ordered select gate lines SGS0, SGS2 and odd-ordered select gate lines SGD1, SGD3 are drawn to the other end of the memory cell array 11. Such the constitution is also applicable. In the constitution, a row decoder selecting the word line WL can be divided into two row decoders to be positioned in opposed sides to sandwich the memory cell array 11. One row decoder can select the select gate lines SGD, SGD2, SGS1, SGS3, the word lines WL0˜WL3, the dummy word lines WLDD and the back gate line BG, and the other row decoder can select the gate line SGS0, SGS2, SGD1, SGD3, the word lines WL4˜WL7 and the dummy word line WLDS. In the constitution, confusion of the select gate lines, wirings of the word lines or the like in a region between a periphery circuit of a row system (row decoder or row driver) and memory cell array 11 can be relaxed.

Furthermore, the constitution of the embodiment can be widely applied to not only NAND-type flash memories but a resistance random access memory (ReRAM) or another semiconductor memory. Signal potentials are not restricted to those described in the embodiment. Others which act in a device can be used.

The configuration of the memory cell array 11 is disclosed in U.S. patent application Ser. No. 12/407,403 filed 19 Mar. 2009 and entitled “three dimensional stacked nonvolatile semiconductor memory”. In addition, the configuration thereof is disclosed in U.S. patent application Ser. No. 12/406,524 filed 18 Mar. 2009 and entitled “three dimensional stacked nonvolatile semiconductor memory”, in U.S. patent application Ser. No. 13/816,799 filed 22 Sep. 2011 and entitled “nonvolatile semiconductor memory device”, and in U.S. patent application Ser. No. 12/532,030 filed 23 Mar. 2009 and entitled “semiconductor memory and method for manufacturing the same”. The entire descriptions of these patent applications are incorporated by reference herein.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
memory cell arrays, each of the memory cell arrays including memory cells;
a clock generator configured to generate clock;
an input-output circuit configured to input and output data;
buses, a portion of each of the buses crossing the memory cell arrays;
switches, each of the switches being placed in the bus;
control circuit configured to control the switches to generate a path which transfers clock and data without overlapping with an activated memory cell as viewed from above.

2. The semiconductor memory device of claim 1, wherein
the bus has a loop shape in which the switches are placed, and a portion of the loop shape overlaps with the memory cell array as viewed from above.

3. The semiconductor memory device of claim 1, further comprising:
sense amplifiers, wherein
the memory cell array includes first and second memory cell arrays, each of the sense amplifier includes a first and second sense amplifiers corresponding to the first and second memory cell arrays, respectively,
each of the bus includes first-third buses,
the switches includes first-eighth switches,
one portion of the first bus overlaps with the first memory cell array and the other portion of the first bus doe not overlap with any of the memory cell arrays, the second bus overlaps with the second memory cell array, and the third bus does not overlap with any of the memory cell arrays, as viewed from above,
the first sense amplifier is configured to connect to the first bus via the first and second switches and to connect to the second bus via the first and third switches, the second sense amplifier is configured to connect to the second bus via the fourth and fifth switches and to connect to the third bus via the fourth and sixth switches, and the third bus is configured to connect to the clock generator and the input-output circuit via the seventh switch, as viewed from above,
the first bus is configured to connect to the clock generator and the input-output circuit via the eighth switch.

4. The semiconductor memory device of claim 3, wherein
a first voltage is applied to gates of the second, fourth and eighth switches and a second voltage is applied to gates of the first, third and fifth-seventh switches in a case that the first memory cell array is activated, the first voltage being lower than the second voltage, and
the first voltage is applied to the gates of the third-seventh switches and the second voltage is applied to the gates of the first, second and eighth switches in a case that the second memory cell array is activated,
when the first sense amplifier is accessed.

5. The semiconductor memory device of claim 3, wherein
the sense amplifier is provided above a semiconductor substrate,
the bus is provided above the sense amplifier,
the memory cell array is provided above the bus, and
the memory cells are three-dimensionally stacked above the semiconductor substrate.

6. The semiconductor memory device of claim 1, further comprising:
sense amplifiers, wherein
the memory cell arrays include first and second memory cell arrays,
the sense amplifiers include the first and second sense amplifiers corresponding to the first and second memory cell arrays, respectively.

7. The semiconductor memory device of claim 6, wherein
each of the sense amplifiers includes a latch circuit,
the first sense amplifier includes a first latch circuit and the second sense amplifier includes a second latch circuit.

8. The semiconductor memory device of claim 2, wherein
the bus includes first-third loop shape buses,
the first loop shape bus connects to the input-output circuit and transfers data outputted from the latch circuit to the input-output circuit,
the second loop shape bus connects to the clock generator and transfers clock signal generated in the clock generator to the latch circuit, and
the third loop shape bus connects to the input-output circuit and transfers clock signal outputted from the latch circuit to the input-output circuit.

9. The semiconductor memory device of claim 8, wherein
each of the first-third loop shape buses includes the first-third buses,
one portion of each of the first buses overlaps with the first memory cell array and the other portion of each of the first buses does not overlap with any of the memory cell arrays, each of the second buses overlaps with the second memory cell array, and each of the third buses does not overlap with any of the memory cell array, as viewed from above,
the switches includes the first-eighth switches,
the sense amplifiers includes the first and second sense amplifiers,
the first sense amplifier is configured to connect to the first bus via the first and second switches, and to connect to the second bus via the first and third switches,
the second sense amplifier is configured to connect to the second bus via the fourth and fifth switches, and to connect to the third bus via the fourth and sixth switches,
the third bus is configured to connect to the clock generator and the input-output circuit via the seventh switch, and
the first bus is configured to connect to the clock generator and the input-output circuit via the eighth switch.

10. The semiconductor memory device of claim 9, wherein
the first voltage is applied to the gates of the second, fourth and eighth switches and the second voltage is applied to the gates of the first, third and fifth-seventh switches in a case that the first memory cell array is activated, and
the first voltage is applied to the gates of the third-seventh switches and the second voltage is applied to the gates of the first, second and eighth switches in a case that the second memory cell array is activated,
when the first sense amplifier is accessed.

11. The semiconductor memory device of claim 9, wherein
the sense amplifier is provided above a semiconductor substrate,
the bus is provided above the sense amplifier,
the memory cell array is provided above the bus, and
the memory cells are three-dimensionally stacked above the semiconductor substrate.

12. The semiconductor memory device of claim 2, wherein
the bus includes first and second loop shape buses,
the first loop shape bus connects to the input-output circuit and transfers data outputted from the latch circuit to the input-output circuit,
the second loop shape bus connects to the clock generator and transfers clock signal generated in the clock generator to the latch circuit.

13. The semiconductor memory device of claim 11, wherein
each of the first-third loop shape buses includes the first-third buses,
one portion of each of the first buses overlaps with the first memory cell array and the other portion of each of the first buses does not overlap with any of the memory cell arrays, each of the second buses overlaps with the second memory cell array, and each of the third buses does not overlap with any of the memory cell array, as viewed from above,
the switches includes the first-eighth switches,
the sense amplifiers includes the first and second sense amplifiers,
the first sense amplifier is configured to connect to the first bus via the first and second switches, and to connect to the second bus via the first and third switches,
the second sense amplifier is configured to connect to the second bus via the fourth and fifth switches, and to connect to the third bus via the fourth and sixth switches,
the third bus is configured to connect to the clock generator and the input-output circuit via the seventh switch, and
the first bus is configured to connect to the clock generator and the input-output circuit via the eighth switch.

14. The semiconductor memory device of claim 13, wherein
the first voltage is applied to the gates of the second, fourth and eighth switches and the second voltage is applied to the gates of the first, third and fifth-seventh switches in a case that the first memory cell array is activated, and
the third-seventh switches are set to be off and the first, second and eighth switches are set to be on in a case that the second memory cell array is activated,
when the first sense amplifier is accessed.

15. The semiconductor memory device of claim 13, wherein
the sense amplifier is provided above a semiconductor substrate,
the bus is provided above the sense amplifier,
the memory cell array is provided above the bus, and
the memory cells are three-dimensionally stacked above the semiconductor substrate.

16. The semiconductor memory device of claim 12, wherein
the first loop shape bus transfers data inputted from the input-output circuit to the latch circuit.
